(19) United States
(12) Patent Application Publication
(10) Pub. No.: US 2025/0107127 A1
(43) Pub. Date: Mar. 27, 2025

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventors: Yuichiro SASAKI, Nonoichi Ishikawa (JP); Takeshi SHIBATA, Nonoichi Ishikawa (JP); Daiki YOSHIKAWA, Kanazawa Ishikawa (JP)

(21) Appl. No.: 18/680,325

(22) Filed: May 31, 2024

(30) Foreign Application Priority Data
Sep. 25, 2023 (JP) 2023-159965

(51) Int. Cl. H01L 29/739; H01L 23/64; H01L 29/04; H01L 29/06; H01L 29/66

(52) U.S. Cl. CPC H10D 12/481; H01L 23/647; H10D 12/038; H10D 62/127; H10D 62/40

(57) ABSTRACT

According to one embodiment, a semiconductor device includes a first electrode, a second electrode separated from the first electrode, and a semiconductor part located between the first electrode and the second electrode. The semiconductor part includes a first region, a second region, and a third region located between the first region and the second region in a second direction perpendicular to a first direction that is from the first electrode toward the second electrode. The third region includes a tenth semiconductor region of the first conductivity type located on the first electrode, and a current blocking region located between the sixth semiconductor region and the ninth semiconductor region in the second direction and located on the tenth semiconductor region.

### CROSS-REFERENCE TO RELATED APPLICATIONS

This application is based upon and claims the benefit of priority from Japanese Patent Application No. 2023-159965, filed on Sep. 25, 2023; the entire contents of which are incorporated herein by reference.

### FIELD

Embodiments of the invention generally relate to a semiconductor device and a method for manufacturing the same.

### BACKGROUND

A semiconductor device is known in which an IGBT and a diode are provided on a single semiconductor substrate and connected in parallel with each other.

### BRIEF DESCRIPTION OF THE DRAWINGS

FIG. 1 is a plan view showing an example of a semiconductor device according to an embodiment;

FIG. 2 is a B1-B2 cross-sectional view of FIG. 1;

FIG. 3 is a flowchart showing an example of manufacturing processes of the semiconductor device according to the embodiment;

FIG. 4 is a cross-sectional view showing a semiconductor part manufactured in the manufacturing process of the semiconductor device according to the embodiment;

FIG. 5 is a cross-sectional view showing the semiconductor part manufactured in the manufacturing process of the semiconductor device according to the embodiment;

FIG. 6 is a cross-sectional view showing the semiconductor part manufactured in the manufacturing process of the semiconductor device according to the embodiment;

FIG. 7 is a cross-sectional view showing the semiconductor part manufactured in the manufacturing process of the semiconductor device according to the embodiment;

FIG. 8 is a cross-sectional view showing the semiconductor part manufactured in the manufacturing process of the semiconductor device according to the embodiment;

FIG. 9 is a cross-sectional view showing the semiconductor part manufactured in the manufacturing process of the semiconductor device according to the embodiment;

FIG. 10 is a cross-sectional view showing the semiconductor part manufactured in the manufacturing process of the semiconductor device according to the embodiment;

FIG. 11 is a cross-sectional view showing the semiconductor part manufactured in a manufacturing process of the semiconductor device according to the embodiment;

FIG. 12 is a cross-sectional view showing the semiconductor part manufactured in the manufacturing process of the semiconductor device according to the embodiment; and

FIG. 13 is a cross-sectional view showing the semiconductor part manufactured in the manufacturing process of the semiconductor device according to the embodiment.

### DETAILED DESCRIPTION

According to one embodiment, a semiconductor device includes a first electrode, a second electrode separated from the first electrode, and a semiconductor part. The semiconductor part is located between the first electrode and the second electrode. The semiconductor part includes a first region, a second region, and a third region located between the first region and the second region in a second direction perpendicular to a first direction that is from the first electrode toward the second electrode. The semiconductor part is located on the first electrode. The semiconductor part is located under the second electrode. The first region includes a first semiconductor region, a second semiconductor region, a third semiconductor region, a gate electrode, a fourth semiconductor region, and a sixth semiconductor region. The first semiconductor region is of a first conductivity type. The second semiconductor region is of a second conductivity type and located on the first semiconductor region. The third semiconductor region is located on the second semiconductor region, and has a lower first-conductivity-type impurity concentration than the first semiconductor region. The gate electrode faces the third semiconductor region via a gate insulating layer in the second direction. The fourth semiconductor region is of the second conductivity type located on the third semiconductor region, and has a higher second-conductivity-type impurity concentration than the second semiconductor region. The sixth semiconductor region is of the second conductivity type and located between the first semiconductor region and the second semiconductor region in the first direction. The second region includes a seventh semiconductor region, an eighth semiconductor region, a ninth semiconductor region, and a conductive part. The seventh semiconductor region is of the second conductivity type and has a higher second-conductivity-type impurity concentration than the second semiconductor region. The second semiconductor region is located on the seventh semiconductor region. The eighth semiconductor region is of the first conductivity type located on the second semiconductor region, and is electrically connected with the second electrode. The ninth semiconductor region is of the second conductivity type located between the second semiconductor region and the seventh semiconductor region in the first direction. The ninth semiconductor region has a higher second-conductivity-type impurity concentration than the second semiconductor region and has a lower second-conductivity-type impurity concentration than the seventh semiconductor region. The conductive part is electrically connected with the second electrode, and includes a portion facing the eighth semiconductor region via an insulating layer in the second direction. The third region includes a tenth semiconductor region and a current blocking region. The tenth semiconductor region is located on the first electrode. The tenth semiconductor region is of the first conductivity type. The current blocking region is located between the sixth semiconductor region and the ninth semiconductor region in the second direction and located on the tenth semiconductor region.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

In the following description, the notations of n⁺, n, n⁻, p⁺, and p indicate relative levels of the impurity concentrations of the conductivity types. Namely, n⁺ indicates that the n-type impurity concentration is relatively higher than that of n; and n⁻ indicates that the n-type impurity concentration is relatively lower than that of n. Also, p⁺ indicates that the p-type impurity concentration is relatively higher than that of p; and p⁻ indicates that the p-type impurity concentration is relatively lower than that of p.

According to the embodiments described below, each embodiment may be implemented by inverting the p-type and the n-type of the semiconductor regions.

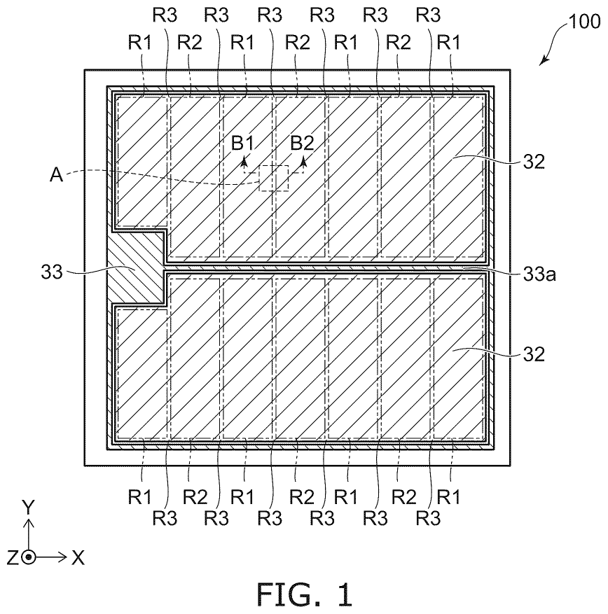

FIG. 1 is a plan view of a semiconductor device according to an embodiment.

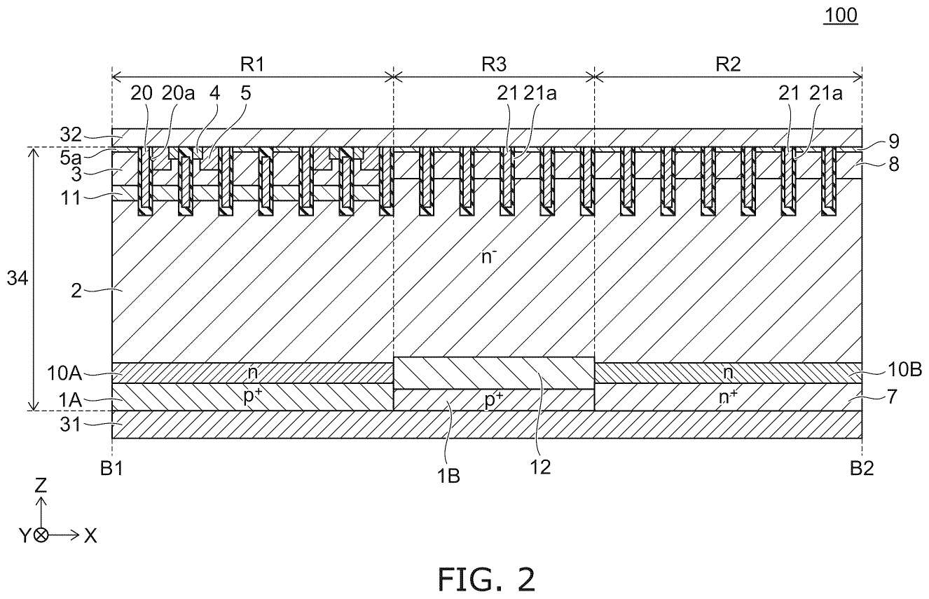

FIG. 2 is a B1-B2 cross-sectional view of FIG. 1.

The semiconductor device according to the embodiment is an RC-IGBT. As shown in FIGS. 1 and 2, the semiconductor device 100 according to the embodiment includes a collector electrode 31 (a first electrode), an emitter electrode 32 (a second electrode), a gate pad 33, and a semiconductor part 34. The semiconductor part 34 includes a p⁺-type (first-conductivity-type) collector region 1A (a first semiconductor region), a p⁺-type (first-conductivity-type) collector region 1B (a tenth semiconductor region), an n⁻-type (second-conductivity-type) base region 2 (a second semiconductor region), a p-type base region 3 (a third semiconductor region), an n⁺-type emitter region 4 (a fourth semiconductor region), a p⁺-type contact region 5 (a fifth semiconductor region), an n⁺-type cathode region 7 (a seventh semiconductor region), a p-type anode region 8 (an eighth semiconductor region), a p⁺-type anode region 9, an n-type buffer region 10A (a sixth semiconductor region), an n-type buffer region 10B (a ninth semiconductor region), an n-type barrier region 11, an oxygen implantation region 12 (a current blocking region), a gate electrode 20, and a conductive part 21.

An XYZ orthogonal coordinate system is used in the description of embodiments. The direction from the collector electrode 31 toward the emitter electrode 32 is taken as a Z-direction (a first direction). Two mutually-orthogonal directions perpendicular to the Z-direction are taken as an X-direction (a second direction) and a Y-direction (a third direction). In the description, the direction from the collector electrode 31 toward the emitter electrode 32 is called “up”, and the opposite direction is called “down”. These directions are based on the relative positional relationship of the collector electrode 31 and the emitter electrode 32, and are independent of the direction of gravity.

As shown in FIG. 1, the emitter electrode 32 and the gate pad 33 are located at the upper surface of the semiconductor device 100. The emitter electrode 32 and the gate pad 33 are separated from each other. For example, multiple 30 emitter electrodes 32 are arranged in the Y-direction. A gate wiring part 33a is located around the emitter electrodes 32. The gate wiring part 33a is electrically connected with the gate pad 33.

As shown in FIG. 2, the semiconductor part 34 of 35 the semiconductor device 100 includes, along the X-direction, an IGBT region R1 (a first region), a diode region R2 (a second region), and a separation region R3 (a third region) located between the IGBT region R1 and the diode region R2; the X-direction is perpendicular to the Z-direction; and the Z-direction is from the collector electrode 31 toward the emitter electrode 32. In the example shown in FIG. 1, pluralities of the IGBT region R1, the diode region R2, and the separation region R3 are arranged in the X-direction and Y-direction. The IGBT region R1 and the diode region R2 are alternately arranged in the X-direction. The separation region R3 is located between the IGBT region R1 and the diode region R2.

As shown in FIG. 2, the collector electrode 31 is located at the lower surface of the semiconductor device 100. The collector electrode 31 and the emitter electrode 32 are separated from each other. The multiple IGBT regions R1, the multiple diode regions R2, and the separation region R3 are positioned between the collector electrode 31 and the emitter electrode 32.

As shown in FIG. 2, each IGBT region R1 includes the p⁺-type collector region 1A, a portion of the n⁻-type base region 2, the p-type base region 3, a p-type contact region 5a, the n⁺-type emitter region 4, the p⁺-type contact region 5, the n-type buffer region 10A, the n-type barrier region 11, and the gate electrode 20.

The p⁺-type collector region 1A is located on a portion of the collector electrode 31, and is electrically connected with the collector electrode 31. A portion of the n⁻-type base region 2 is located on the p⁺-type collector region 1A. The p-type base region 3 is located on the portion of the n⁻-type base region 2, and is positioned on the p⁺-type collector region 1A. The gate electrode 20 faces the p-type base region 3 via a gate insulating layer 20a in the X-direction.

The n-type buffer region 10A is located between the p⁺-type collector region 1A and the portion of the n⁻-type base region 2. The n-type impurity concentration of the n-type buffer region 10A is less than the n-type impurity concentration of the n⁺-type cathode region 7 and greater than the n-type impurity concentration of the n⁻-type base region 2. By including the n-type buffer region 10A, the spreading of the depletion layer in the n⁻-type base region 2 can be more reliably suppressed by the n-type buffer region 10A.

As shown in FIG. 2, the n⁺-type emitter region 4 is located on the p-type base region 3. The emitter electrode 32 is located on the collector electrode 31. The emitter electrode 32 is located on the n⁺-type emitter region 4. The n⁺-type emitter region 4 is arranged with the p⁺-type contact region 5 in the X-direction. The p⁺-type contact region 5 may be a p-type contact region. The p-type contact region 5a is located between the p-type base region 3 and the emitter electrode 32 in the Z-direction.

The p⁺-type contact region 5 is located on the p-type base region 3, and is arranged with the n⁺-type emitter region 4 in the X-direction. The p-type impurity concentration of the p⁺-type contact region 5 is greater than the p-type impurity concentration of the p-type base region 3.

A Y-direction end portion of the gate electrode 20 is electrically connected with the gate wiring part 33a.

As shown in FIG. 2, pluralities of the p-type base region 3, the n⁺-type emitter region 4, the p⁺-type contact region 5, and the gate electrode 20 are arranged in the X-direction. The multiple p-type base regions 3 and the multiple gate electrodes 20 each are provided in stripe shapes, and extend in the Y-direction.

Each diode region R2 includes the n⁺-type cathode region 7, another portion of the n⁻-type base region 2, the p-type anode region 8, the p⁺-type anode region 9, the n-type buffer region 10B, and the conductive part 21. The n⁺-type cathode region 7 is located on the other portion of the collector electrode 31, and is electrically connected with the collector electrode 31. The other portion of the n⁻-type base region 2 is located on the n⁺-type cathode region 7. The p-type anode region 8 is located on the other portion of the n⁻-type base region 2, and is positioned on the n⁺-type cathode region 7.

The n-type buffer region 10B is located between the n⁺-type cathode region 7 and the other portion of the n⁻-type base region 2. The n-type impurity concentration of the n-type buffer region 10B is less than the n-type impurity concentration of the n⁺-type cathode region 7 and greater than the n-type impurity concentration of the n⁻-type base region 2. By including the n-type buffer region 10B, the spreading of the depletion layer in the other portion of the n⁻-type base region 2 can be more reliably suppressed by the n-type buffer region 10B.

The conductive part 21 faces the p-type anode region 8 via an insulating layer 21a in the X-direction. The p⁺-type anode region 9 is located on the p-type anode region 8. The p-type impurity concentration of the p⁺-type anode region 9 is greater than the p-type impurity concentration of the p-type anode region 8. The p-type anode region 8, the p⁺-type anode region 9, and the conductive part 21 are electrically connected with the emitter electrode 32.

Pluralities of the p-type anode region 8, the p⁺-type anode region 9, and the conductive part 21 are arranged in the X-direction. The multiple p-type anode regions 8, the multiple p⁺-type anode regions 9, and the multiple conductive parts 21 each are provided in stripe shapes, and extend in the Y-direction.

Each separation region R3 includes the p⁺-type collector region 1B, the p-type anode region 8, the p⁺-type anode region 9, one other portion of the n⁻-type base region 2, the conductive part 21, and the oxygen implantation region 12. The p⁺-type collector region 1B is located on the one other portion of the collector electrode 31, and is electrically connected with the collector electrode 31. The oxygen implantation region 12 is located on the p⁺-type collector region 1B. The one other portion of the n⁻-type base region 2 is located on the oxygen implantation region 12. The p-type anode region 8, the p⁺-type anode region 9, and the conductive part 21 are provided similarly to those of the diode regions R2.

The oxygen implantation region 12 is located between the n-type buffer region 10A and the n-type buffer region 10B in the X-direction. In the Z-direction, the thickness of the oxygen implantation region 12 is greater than the thicknesses of the n-type buffer regions 10A and 10B. Although the oxygen implantation region 12 is described as being implanted with oxygen in the embodiment, another material instead of oxygen may be included. That is, for example, when silicon is a major material of the n-type buffer region 10A, it is sufficient to implant a material that reacts with silicon and is insulative. The material may be at least one selected from the group consisting of oxygen, carbon, and nitrogen.

Examples of impurity concentrations of the p⁺-type collector regions 1A and 1B, the n⁻-type base region 2, the n⁺-type cathode region 7, the n-type buffer region 10A, the n-type buffer region 10B, and the oxygen implantation region 12 will now be described.

The first-conductivity-type impurity concentration in the p⁺-type collector regions 1A and 1B is 1×10¹⁷ cm⁻³ to 1×10¹⁸ cm⁻³. The second-conductivity-type impurity concentration in the n⁻-type base region 2 is 1×10¹⁴ cm⁻³. The second-conductivity-type impurity concentration in the n⁺-type cathode region 7 is 1×10¹⁸ cm⁻³ to 2×10²⁰ cm³. The second-conductivity-type impurity concentrations in the n-type buffer regions 10A and 10B are 1×10¹⁶ cm⁻³. The oxygen implantation region 12 includes the second-conductivity-type impurity and oxygen as impurities. In the oxygen implantation region 12, the concentration of the second-conductivity-type impurity is 1×10¹⁶ cm⁻³; and the oxygen concentration may be 3×10¹⁷ cm⁻³ to 3×10¹⁹ cm⁻³, but is desirably not less than 1×10¹⁸ cm⁻³.

Operations of the semiconductor device 100 will now be described.

A voltage that is not less than a threshold is applied to the gate electrode 20 in a state in which a positive voltage with respect to the emitter electrode 32 is applied to the collector electrode 31. As a result, a channel (an inversion layer) is formed in the p-type base region 3. Electrons flow from the n⁺-type emitter region 4 toward the n⁻-type base region 2 via the channel; and holes flow from the p⁺-type collector region 1A toward the n⁻-type base region 2. The density of carriers accumulated in the n⁻-type base region 2 increases, and conductivity modulation occurs. As a result, the electrical resistance in the n⁻-type base region 2 greatly decreases, and the IGBT region R1 is set to an on-state. Subsequently, when the voltage applied to the gate electrode 20 drops below the threshold, the channel in the p-type base region 3 disappears, and the IGBT region R1 is switched to an off-state.

After the IGBT region R1 is switched to the off-state, the electrons that accumulated in the n⁻-type base region 2 are discharged to the collector electrode 31 via a p⁺-type collector region 1. The holes are discharged to the emitter electrode 32 via the p-type base region 3.

For example, a bridge circuit is configured using multiple semiconductor devices 100. When one semiconductor device 100 is switched from the on-state to the off-state, an induced electromotive force is applied to the emitter electrode 32 of another semiconductor device 100 by an inductance component of the bridge circuit. As a result, the diode region R2 of the other semiconductor device 100 operates. Holes flow from the p-type anode region 8 to the n⁻-type base region 2; and electrons flow from the n⁺-type cathode region 7 to the n⁻-type base region 2. The diode region R2 functions as a freewheeling diode (FWD).

In the semiconductor device 100, the oxygen concentration in the oxygen implantation region 12 of the separation region R3 is greater than those of the n-type buffer regions 10A and 10B. Therefore, the electrical resistivity and crystal defect density of the oxygen implantation region 12 are large. The carrier lifetime can be reduced thereby. For example, the crystal defect density can be defined as the number of defects and foreign matter causing defects in the manufacturing processes per unit area. For example, the crystal defect density can be measured by observing a cross section of the semiconductor device 100 with TEM (transmission electron microscopy). The observation object of TEM is, for example, at least one of dark spots in a cross section, deep levels in DLTS (Deep Level Transient Spectroscopy) or the like, lattice defects, or point defects.

For example, the oxygen implantation region 12 can drastically suppress the current flowing from the n-type buffer region 10A to the n-type buffer region 10B in the X-direction in the operation of the semiconductor device 100 described above. Therefore, the IGBT region R1 and the diode region R2 can be electrically isolated under the n⁻-type base region 2 of the semiconductor device 100.

For example, in the IGBT operation of the semiconductor device 100, the oxygen implantation region 12 can suppress the current flowing from the n-type buffer region 10A to the n-type buffer region 10B before the current exceeds the built-in potential of the p⁺-type collector region 1. Accordingly, a unipolar operation of the semiconductor device 100 can be suppressed.

The n-type barrier region 11 may be located between the n⁻-type base region 2 and the p-type base region 3. By including the n-type barrier region 11, the discharge of holes accumulated in the n⁻-type base region 2 when the IGBT region R1 is in the on-state can be suppressed, and the carrier density in the n⁻-type base region 2 can be increased. The electrical resistance when the IGBT region R1 is in the on-state can be reduced thereby.

In the IGBT region R1, some of the multiple gate electrodes 20 may be replaced with the conductive part 21. By replacing some of the gate electrodes 20 with the conductive part 21, the carrier density in the n⁻-type base region 2 when the IGBT region R1 is in the on-state can be increased, and the electrical resistance of the semiconductor device 100 can be further reduced.

Examples of the materials of the components of the semiconductor device 100 will now be described.

The p⁺-type collector regions 1A and 1B, the n⁻-type base region 2, the p-type base region 3, the n⁺-type emitter region 4, the p⁺-type contact region 5, the n⁺-type cathode region 7, the p-type anode region 8, the p⁺-type anode region 9, the n-type buffer regions 10A and 10B, and the n-type barrier region 11 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity.

The gate electrode 20 and the conductive part 21 include conductive materials such as polysilicon, etc. The gate insulating layer 20a and the insulating layer 21a include insulating materials such as silicon oxide, silicon nitride, silicon oxynitride, etc. The collector electrode 31, the emitter electrode 32, the gate pad 33, and the gate wiring part 33a include metals such as aluminum, etc.

A method for manufacturing the semiconductor device 100 shown in FIG. 1 will now be described.

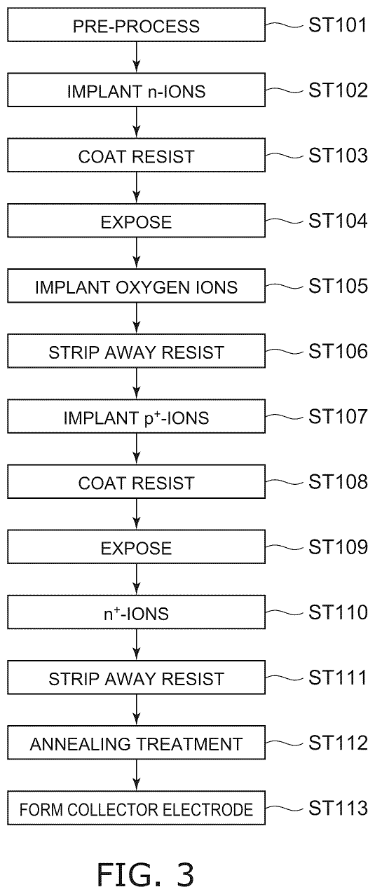

FIG. 3 is a flowchart showing an example of the manufacturing processes of the semiconductor device 100.

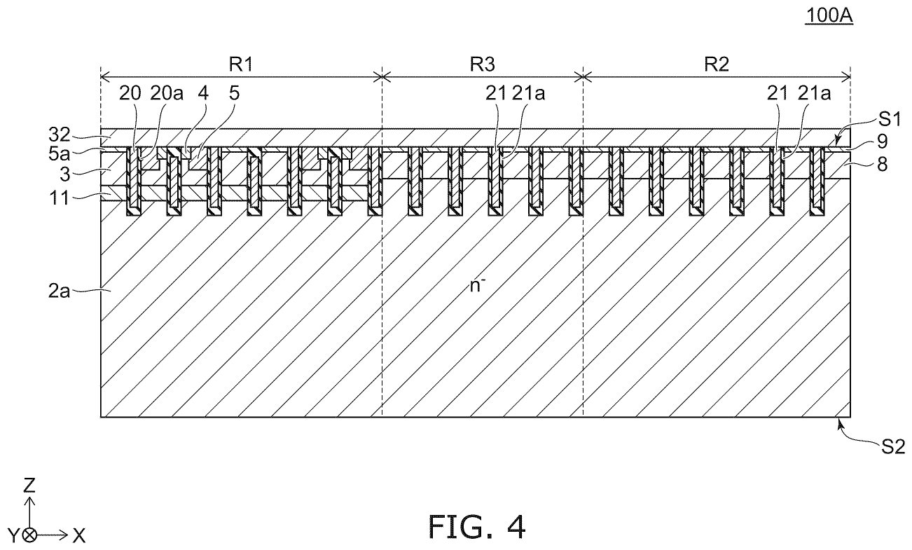

FIGS. 4 to 13 show examples of cross sections of semiconductor parts 100A to 100J in the manufacturing processes.

First, a pre-process is performed (ST101). The pre-process is a process of forming the IGBT region R1, the diode region R2, and the separation region R3 on the n⁻-type base region 2. In other words, the pre-process is performed before the processes of the back surface of the RC-IGBT. FIG. 4 shows an example of a cross section of the semiconductor part 100A manufactured by the pre-process.

In the semiconductor part 100A as shown in FIG. 4, the p-type base region 3, the n⁺-type emitter region 4, the p⁺-type contact region 5, the p-type anode region 8, the p⁺-type anode region 9, the gate electrode 20, the conductive part 21, and the emitter electrode 32 are formed on an n⁻-type base region 2a.

More specifically, the semiconductor part 100A includes an upper surface S1 (a first surface) and a lower surface S2 (a second surface) opposite to the upper surface S1. The IGBT region R1 of the semiconductor part 100A includes a portion of the n⁻-type base region 2 (a first sub-region), the p-type base region 3 (a second sub-region), the n⁺-type emitter region 4 (a third sub-region), and the gate electrode 20. The diode region R2 of the semiconductor part 100A includes another part of the n⁻-type base region 2, the p-type anode region 8 (a fourth sub-region), the p⁺-type anode region 9, and the conductive part 21. The isolation region R3 of the semiconductor part 100A includes still another part of the n⁻-type base region 2, the p-type anode region 8, the p⁺-type anode region 9, and the conductive part 21. The emitter electrode 32 is formed on the upper surface S1 of the semiconductor part 100A.

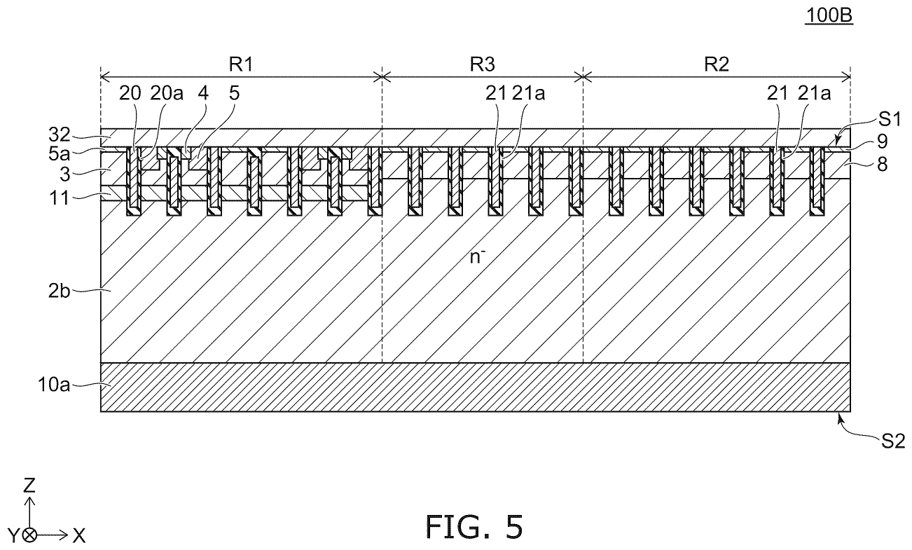

After the pre-process, n-ions are implanted (ST102). The n-ions are a second-conductivity-type (according to the embodiment, n-type) impurity, e.g., ionized phosphorus. The n-ions are implanted in the Z-direction from under the semiconductor part 100A. As a result, an n-type buffer region 10a (a fifth sub-region) is formed in a portion of the n⁻-type base region 2a of the semiconductor part 100A. The region of the n-type base region 2a where the n-type buffer region 10a is not formed becomes an n-type base region 2b. As shown in FIG. 5, the n-type buffer region 10a is located under the n-type base region 2b in the semiconductor part 100B. The second-conductivity-type impurity concentration of the n-type buffer region 10a is, for example, 1×10¹⁶ cm⁻³. The n-type buffer region 10a of the desired thickness is formed by, for example, a three-step implantation of the second-conductivity-type impurity. Here, three-step implantation is a method in which ion implantation is performed three times with different ion implantation conditions. As a result, n-ions can be implanted to three different depths in the Z-direction.

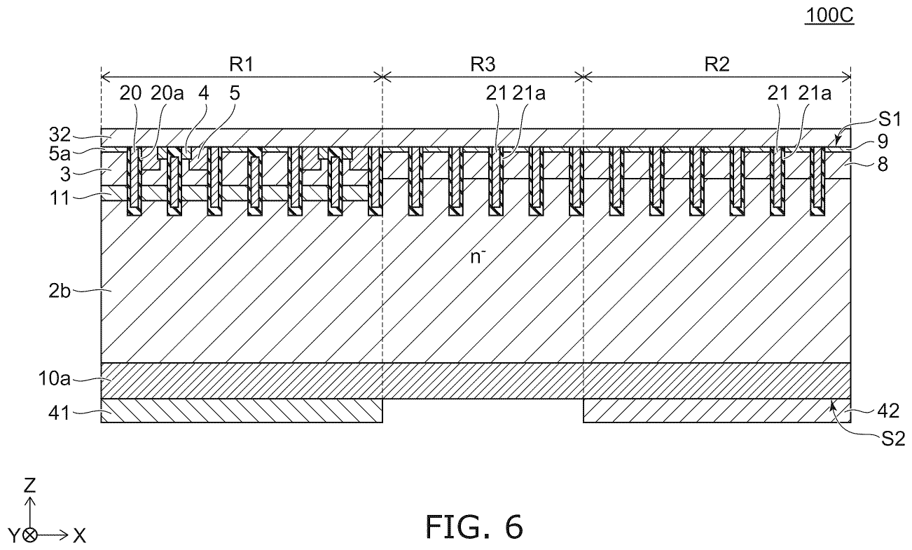

Continuing, a resist is coated (ST103) and exposed (ST104). The resist is coated onto the entire surface of the lower surface S2 of the n-type buffer region 10a. Then, for example, the portion of the resist in the separation region R3 is exposed via a prescribed mask, and then developed and removed. As a result, the resist that is coated onto the lower surface S2 of the semiconductor part 100B in the separation region R3 disappears; and an opening is formed. In the semiconductor part 100C as shown in FIG. 6, a resist 41 is formed in the IGBT region R1; and a resist 42 is formed in the diode region R2. In other words, an opening is formed in the resist located at the lower surface S2 of the semiconductor part 100C in the separation region R3.

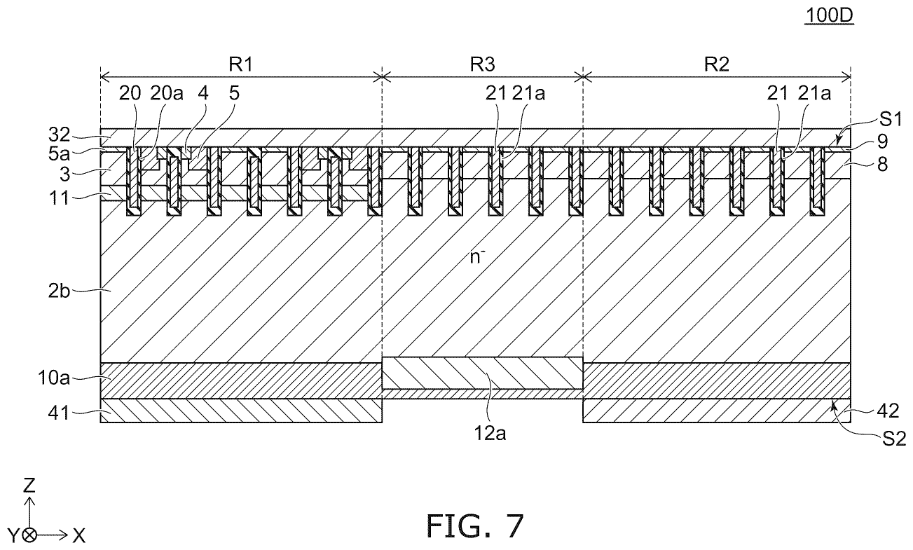

Then, oxygen ions are implanted (ST105). The oxygen ions are implanted into the semiconductor part 100C in the separation region R3 via the opening of the resist. The implantation conditions of the oxygen ions are, for example, a temperature of 0°° C., 1500 keV, 1×10¹³ to 1×10¹⁵ cm⁻², an implantation angle (tilt) of 7°, and an implantation twist angle (twist) of 23°. The dose of the oxygen ions is set so that the peak concentration of the oxygen ions is not less than the second-conductivity-type impurity concentrations in at least the n-type buffer regions 10A and 10B. It is desirable to implant the oxygen ions to be deeper than the thicknesses of the n-type buffer regions 10A and 10B in the Z-direction. As a result, an oxygen implantation region 12a is formed between the n⁻-type base region 2a and the n-type buffer region 10a in the separation region R3 of the semiconductor part 100D as shown in FIG. 7.

Boron ions may be implanted before implanting the oxygen ions. For example, the boron ions are implanted with 750 keV, 3.4×10¹¹ cm⁻², an implantation angle (tilt) of 7°, and an implantation twist angle (twist) of 23°; or with 1400 keV, 1.5×10¹¹ cm⁻², an implantation angle (tilt) of 7°, and an implantation twist angle (twist) of 23°.

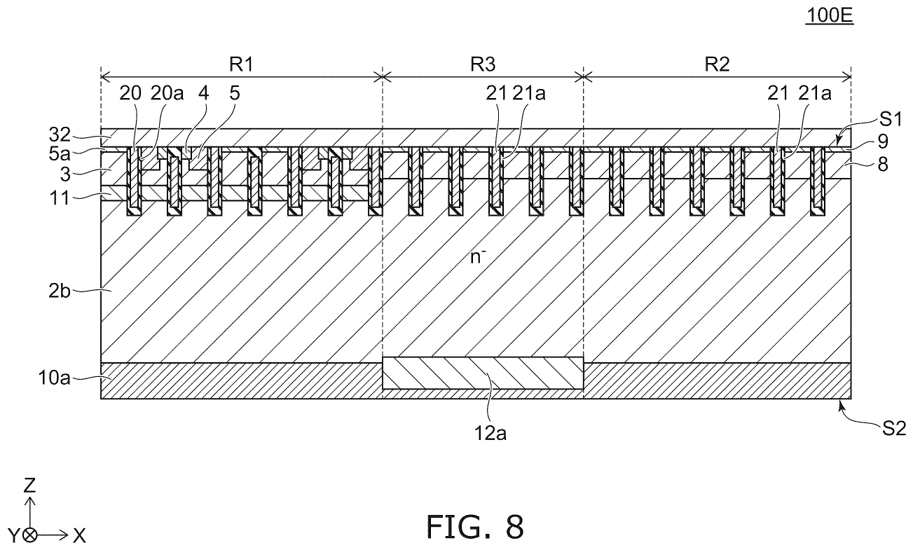

Then, the resist is stripped away (ST106). As a result, the resists 41 and 42 are stripped away from the semiconductor part 100D; and the semiconductor part 100E shown in FIG. 8 is manufactured.

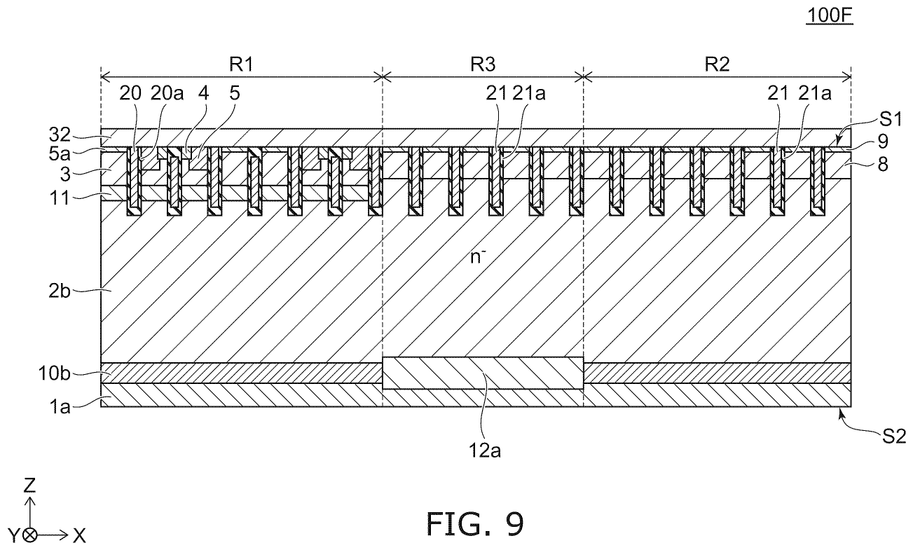

Continuing, p⁺-ions are implanted (ST107). The p⁺-ions are a first-conductivity-type (according to the embodiment, p-type) impurity, e.g., ionized boron. The p⁺-ions are implanted into the entire surface of the lower surface of the semiconductor part 100E shown in FIG. 8. As a result, a p⁺-type collector region is formed in a partial region of the n-type buffer region 10a of the semiconductor part 100E. In the separation region R3, the p⁺-type collector region is formed to be connected with the oxygen implantation region 12a. The region of the n-type buffer region 10a where the p⁺-type collector region is not formed becomes an n-type buffer region 10b. In the semiconductor part 100F as shown in FIG. 9, a p⁺-type collector region 1a (a sixth sub-region) is located under the n-type buffer region 10b.

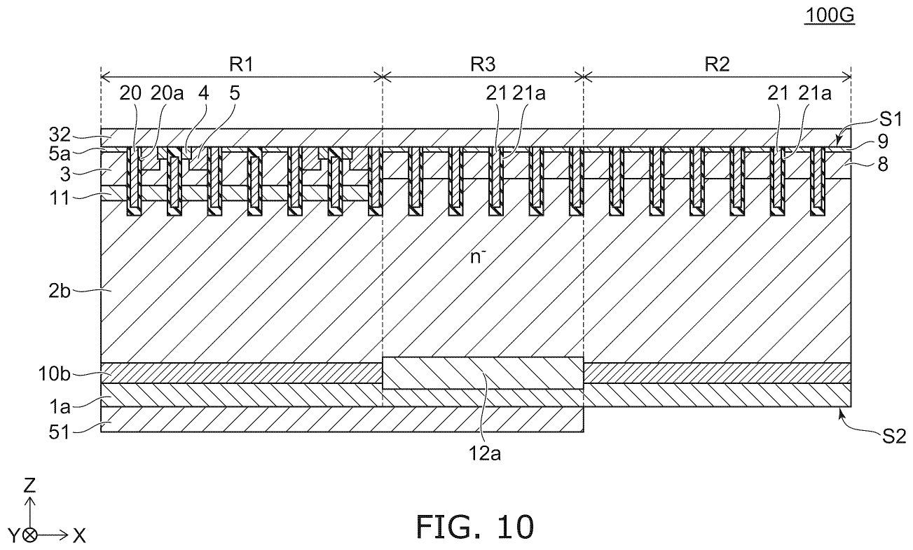

Then, a resist is coated (ST108) and exposed (ST109). The resist is coated onto the entire surface of the lower surface S2 of the p⁺-type collector region 1a. Then, for example, a prescribed mask is used to expose and then develop the resist to form an opening in the portion of the resist on the diode region R2. As a result, the resist in the diode region R2 coated onto the lower surface S2 of the semiconductor part 100F disappears; and an opening is formed. In the semiconductor part 100G as shown in FIG. 10, a resist 51 is formed in the IGBT region R1 and the separation region R3. In other words, the opening is formed in the resist 51 on the lower surface S2 of the semiconductor part 100G in the diode region R2.

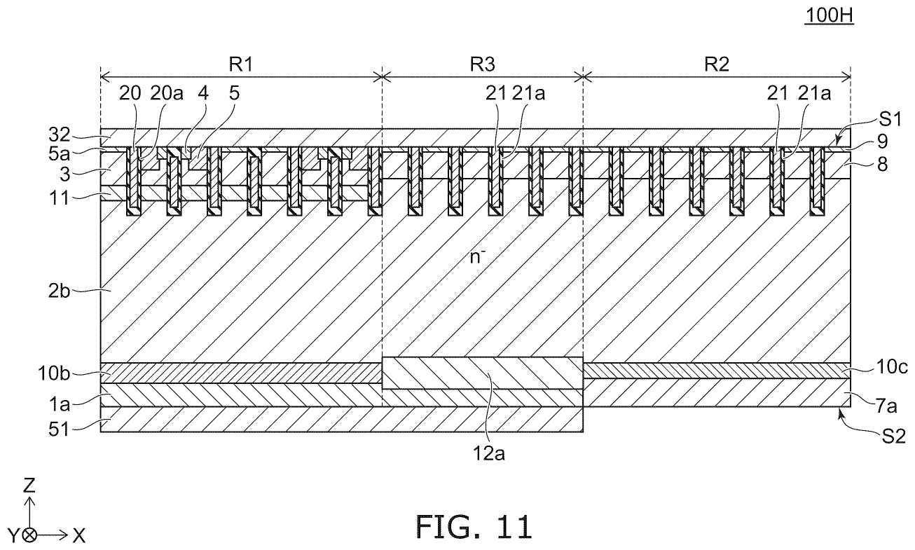

Continuing, n⁺-ions are implanted (ST110). The n⁺-ions are a second-conductivity-type (according to the embodiment, n-type) impurity, e.g., ionized phosphorus. The implantation amount of the ionized phosphorus is greater than the implantation amount of the n-ions described above. In the semiconductor part 100G shown in FIG. 10, the n⁺-ions are implanted into the lower surface S2 of the diode region R2 via the opening of the resist 51. As a result, the second-conductivity-type impurity concentration in a partial region of the n-type buffer region 10b is increased. An n⁺-type cathode region 7a is formed in the region of the n-type buffer region 10b having the higher second-conductivity-type impurity concentration. The region of the n-type buffer region 10b in the diode region R2 where the n⁺-type cathode region 7a is not formed becomes an n-type buffer region 10c. As shown in FIG. 11, the n-type buffer region 10c and the n⁺-type cathode region 7a are located in the diode region R2 of the semiconductor part 100H. The n⁺-type cathode region 7a is located under the n-type buffer region 10c.

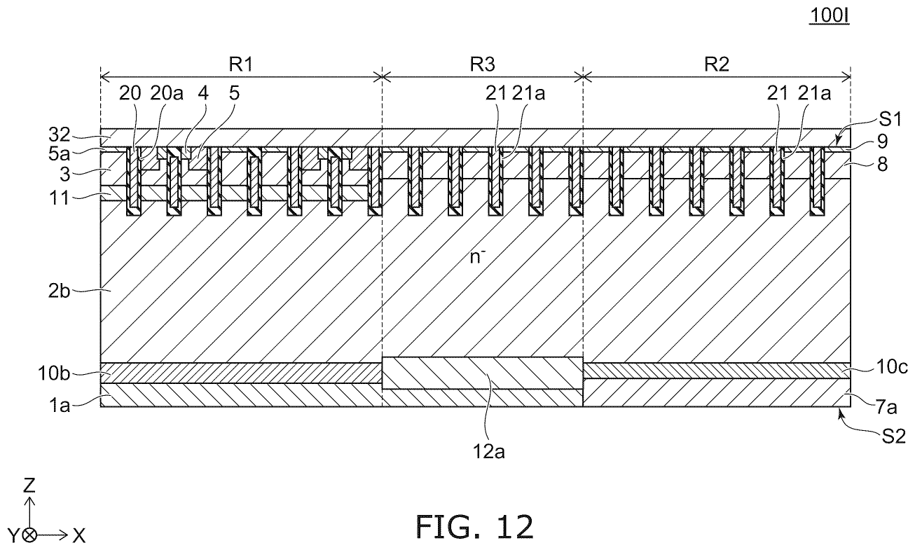

Then, the resist is stripped away (ST111). As a result, the resist 51 is stripped away from the semiconductor part 100H shown in FIG. 11; and the semiconductor part 100I shown in FIG. 12 is manufactured.

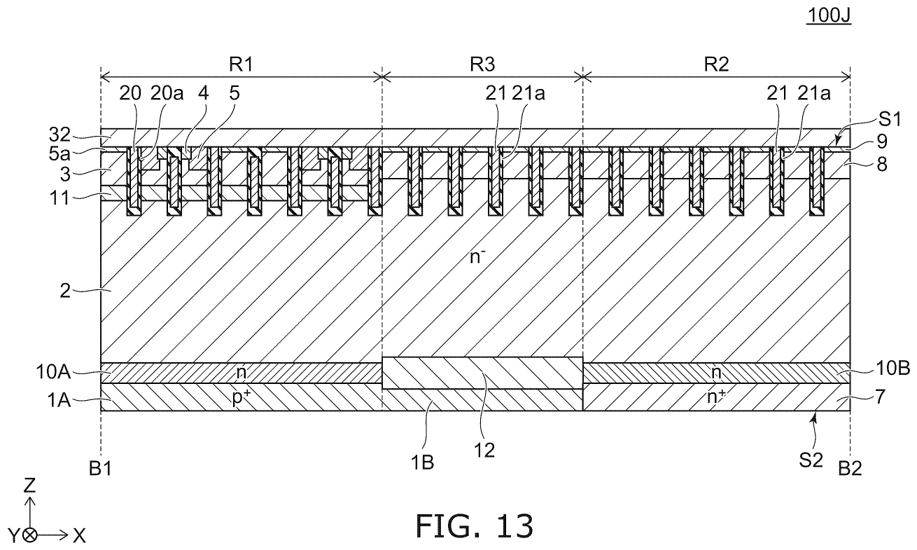

Continuing, annealing treatment is performed (ST112). The p⁺-type collector region 1a, the n-type buffer region 10b, the n-type buffer region 10c, the n⁺-type cathode region 7a, and the oxygen implantation region 12a of the semiconductor part 100H are activated thereby. After activation, the p⁺-type collector region 1a, the n-type buffer region 10b, the n-type buffer region 10c, the n⁺-type cathode region 7a, and the oxygen implantation region 12a respectively become the p⁺-type collector regions 1A and 1B, the n-type buffer region 10A, the n-type buffer region 10B, the n⁺-type cathode region 7, and the oxygen implantation region 12. As shown in FIG. 13, the semiconductor part 100J after annealing treatment is performed includes the p⁺-type collector regions 1A and 1B, the n-type buffer regions 10A and 10B, the n⁺-type cathode region 7, and the oxygen implantation region 12.

Then, a collector electrode is formed (ST113). The collector electrode 31 is formed under the semiconductor part 100J shown in FIG. 13. The semiconductor device 100 shown in FIG. 1 is manufactured thereby.

According to the manufacturing method, the semiconductor device 100 can be manufactured in which the oxygen implantation region 12 located on the p⁺-type collector region 1B and located between the n-type buffer region 10A and the n-type buffer region 10B in the X-direction.

The embodiments may include the following aspects.

### (Note 1)

A semiconductor device, comprising:
a first electrode;
a second electrode separated from the first electrode; and
a semiconductor part located between the first electrode and the second electrode,
the semiconductor part including a first region, a second region, and a third region,
the third region being located between the first region and the second region in a second direction perpendicular to a first direction,
the first direction being from the first electrode toward the second electrode,
the semiconductor part being located on the first electrode and located under the second electrode,
the first region including
   a first semiconductor region of a first conductivity type,
   a second semiconductor region located on the first semiconductor region, the second semiconductor region being of a second conductivity type,
   a third semiconductor region located on the second semiconductor region, the third semiconductor region having a lower first-conductivity-type impurity concentration than the first semiconductor region,
   a gate electrode facing the third semiconductor region via a gate insulating layer in the second direction,
   a fourth semiconductor region located on the third semiconductor region, the fourth semiconductor region being of the second conductivity type, the fourth semiconductor region having a higher second-conductivity-type impurity concentration than the second semiconductor region, and
   a sixth semiconductor region located between the first semiconductor region and the second semiconductor region in the first direction, the sixth semiconductor region being of the second conductivity type,
the second region including
   a seventh semiconductor region of the second conductivity type, the seventh semiconductor region having a higher second-conductivity-type impurity concentration than the second semiconductor region,
   the second semiconductor region located on the seventh semiconductor region,
   an eighth semiconductor region located on the second semiconductor region, the eighth semiconductor region being electrically connected with the second electrode, the eighth semiconductor region being of the first conductivity type,
   a ninth semiconductor region located between the second semiconductor region and the seventh semiconductor region in the first direction, the ninth semiconductor region being of the second conductivity type, the ninth semiconductor region having a higher second-conductivity-type impurity concentration than the second semiconductor region and a lower second-conductivity-type impurity concentration than the seventh semiconductor region, and
   a conductive part electrically connected with the second electrode, a portion of the conductive part facing the eighth semiconductor region via an insulating layer in the second direction,
the third region including
   a tenth semiconductor region located on the first electrode, the tenth semiconductor region being of the first conductivity type, and
   a current blocking region located between the sixth semiconductor region and the ninth semiconductor region in the second direction and located on the tenth semiconductor region.

### (Note 2)

The device according to Note 1, further comprising:
a fifth semiconductor region located on the third semiconductor region,
the fifth semiconductor region being of the first conductivity type,
the fifth semiconductor region having a higher first-conductivity-type impurity concentration than the third semiconductor region.

### (Note 3)

The device according to Note 1 or 2, wherein
the current blocking region includes at least one of oxygen, nitrogen, silicon dioxide, or carbon.

### (Note 4)

The device according to any one of Notes 1 to 3, wherein
a concentration of one of oxygen, nitrogen, silicon dioxide, or carbon included in the current blocking region is greater than a second-conductivity-type impurity concentration of the sixth semiconductor region and the second-conductivity-type impurity concentration of the ninth semiconductor region.

### (Note 5)

The device according to Note 4, wherein
the concentration of the one of oxygen, nitrogen, silicon dioxide, or carbon is not less than 1×10¹⁸ cm⁻³.

### (Note 6)

The device according to any one of Notes 1 to 5, wherein
an electrical resistivity of the current blocking region is greater than an electrical resistivity of the sixth semiconductor region and greater than an electrical resistivity of the ninth semiconductor region.

### (Note 7)

The device according to any one of Notes 1 to 6, wherein
a crystal defect density of the current blocking region is greater than a crystal defect density of the sixth semiconductor region and greater than a crystal defect density of the ninth semiconductor region.

### (Note 8)

A method for manufacturing a semiconductor device, the method comprising:
forming a semiconductor part, the semiconductor part including a first region, a second region, a third region, and a first semiconductor layer, the third region being located between the first region and the second region, the semiconductor part having a first surface and a second surface opposite to the first surface,
the first region including
   a first sub-region of a second conductivity type,
   a second sub-region of a first conductivity type located on the first sub-region,
   a third sub-region of the second conductivity type located on the second sub-region, and
   a gate electrode facing the second sub-region via a gate insulating layer in a second direction connecting the first region and the second region,
the second region including
   the first sub-region,
   a fourth sub-region of the first conductivity type located on the first sub-region, and
   a conductive part facing the fourth sub-region via an insulating layer in the second direction,
the third region including the first sub-region;
forming a first electrode on the first surface of the first region, the second region, and the third region;
forming a fifth sub-region on the second surface, the fifth sub-region having a higher second-conductivity-type impurity concentration than the first sub-region;
coating a first resist onto the second surface;
removing a portion of the first resist located under the third region to form an opening in the first resist;
implanting at least one selected from the group consisting of oxygen, nitrogen, silicon dioxide, and carbon into a portion of the fifth sub-region via the first opening; and
removing the first resist that was coated onto the first region and the second region.

### (Note 9)

The method according to note 8, further comprising:
forming a sixth sub-region of the first conductivity type located under the fifth sub-region by implanting an impurity of the first conductivity type to the second surface on which the first resist was removed.

### (Note 10)

The method according to note 9, further comprising:
coating a second resist onto the second surface after forming the sixth sub-region, the second resist being located under the first region, the second region, and the third region;
removing a portion of the second resist that was coated under the second region to form a second opening;
implanting an impurity of the second conductivity type to the sixth sub-region of the second region via the second opening; and
removing the second resist.

While certain embodiments of the inventions have been illustrated, these embodiments have been presented by way of example only, and are not intended to limit the scope of the inventions. These novel embodiments may be embodied in a variety of other forms; and various omissions, substitutions, modifications, etc., can be made without departing from the spirit of the inventions. These embodiments and their modifications are within the scope and spirit of the inventions and are within the scope of the inventions described in the claims and their equivalents. The embodiments described above can be implemented in combination with each other.

What is claimed is:

1. A semiconductor device, comprising:
a first electrode;
a second electrode separated from the first electrode; and
a semiconductor part located between the first electrode and the second electrode,
the semiconductor part including a first region, a second region, and a third region,
the third region being located between the first region and the second region in a second direction perpendicular to a first direction,
the first direction being from the first electrode toward the second electrode,
the semiconductor part being located on the first electrode and located under the second electrode,
the first region including
a first semiconductor region of a first conductivity type,
a second semiconductor region located on the first semiconductor region, the second semiconductor region being of a second conductivity type,
a third semiconductor region located on the second semiconductor region, the third semiconductor region having a lower first-conductivity-type impurity concentration than the first semiconductor region,
a gate electrode facing the third semiconductor region via a gate insulating layer in the second direction,
a fourth semiconductor region located on the third semiconductor region, the fourth semiconductor region being of the second conductivity type, the fourth semiconductor region having a higher second-conductivity-type impurity concentration than the second semiconductor region, and
a sixth semiconductor region located between the first semiconductor region and the second semiconductor region in the first direction, the sixth semiconductor region being of the second conductivity type,
the second region including
a seventh semiconductor region of the second conductivity type, the seventh semiconductor region having a higher second-conductivity-type impurity concentration than the second semiconductor region,
the second semiconductor region located on the seventh semiconductor region,
an eighth semiconductor region located on the second semiconductor region, the eighth semiconductor region being electrically connected with the second electrode, the eighth semiconductor region being of the first conductivity type,
a ninth semiconductor region located between the second semiconductor region and the seventh semiconductor region in the first direction, the ninth semiconductor region being of the second conductivity type, the ninth semiconductor region having a higher second-conductivity-type impurity concentration than the second semiconductor region and a lower second-conductivity-type impurity concentration than the seventh semiconductor region, and
a conductive part electrically connected with the second electrode, a portion of the conductive part facing the eighth semiconductor region via an insulating layer in the second direction,
the third region including
a tenth semiconductor region located on the first electrode, the tenth semiconductor region being of the first conductivity type, and
a current blocking region located between the sixth semiconductor region and the ninth semiconductor region in the second direction and located on the tenth semiconductor region.

2. The device according to claim 1, further comprising:
a fifth semiconductor region located on the third semiconductor region,
the fifth semiconductor region being of the first conductivity type,
the fifth semiconductor region having a higher first-conductivity-type impurity concentration than the third semiconductor region.

3. The device according to claim 1, wherein
the current blocking region includes at least one of oxygen, nitrogen, silicon dioxide, or carbon.

4. The device according to claim 1, wherein
a concentration of one of oxygen, nitrogen, silicon dioxide, or carbon included in the current blocking region is greater than a second-conductivity-type impurity concentration of the sixth semiconductor region and the second-conductivity-type impurity concentration of the ninth semiconductor region.

5. The device according to claim 4, wherein
the concentration of the one of oxygen, nitrogen, silicon dioxide, or carbon is not less than 1×10¹⁸ cm⁻³.

6. The device according to claim 1, wherein
an electrical resistivity of the current blocking region is greater than an electrical resistivity of the sixth semiconductor region and greater than an electrical resistivity of the ninth semiconductor region.

7. The device according to claim 1, wherein
a crystal defect density of the current blocking region is greater than a crystal defect density of the sixth semiconductor region and greater than a crystal defect density of the ninth semiconductor region.

8. A method for manufacturing a semiconductor device, the method comprising:
forming a semiconductor part, the semiconductor part including a first region, a second region, and a third region, the third region being located between the first region and the second region, the semiconductor part having a first surface and a second surface opposite to the first surface,
the first region including
a first sub-region of a second conductivity type,
a second sub-region of a first conductivity type located on the first sub-region,
a third sub-region of the second conductivity type located on the second sub-region, and
a gate electrode facing the second sub-region via a gate insulating layer in a second direction connecting the first region and the second region,
the second region including
the first sub-region,
a fourth sub-region of the first conductivity type located on the first sub-region, and
a conductive part facing the fourth sub-region via an insulating layer in the second direction,
the third region including the first sub-region;
forming a first electrode on the first surface of the first region, the second region, and the third region;
forming a fifth sub-region on the second surface, the fifth sub-region having a higher second-conductivity-type impurity concentration than the first sub-region;
coating a first resist onto the second surface;
removing a portion of the first resist located under the third region to form an opening in the first resist;
implanting at least one selected from the group consisting of oxygen, nitrogen, and carbon into a portion of the fifth sub-region via the first opening; and
removing the first resist that was coated onto the first region and the second region.

9. The method according to claim 8, further comprising:
forming a sixth sub-region of the first conductivity type located under the fifth sub-region by implanting an impurity of the first conductivity type to the second surface on which the first resist was removed.

10. The method according to claim 9, further comprising:
coating a second resist onto the second surface after forming the sixth sub-region, the second resist being located under the first region, the second region, and the third region;
removing a portion of the second resist that was coated under the second region to form a second opening;
implanting an impurity of the second conductivity type to the sixth sub-region of the second region via the second opening; and
removing the second resist.
